(19) United States
(12) Patent Application Publication
(10) Pub. No.: US 2010/0283501 A1
(43) Pub. Date: Nov. 11, 2010

(54) TESTING METHOD FOR OPTICAL TOUCH PANEL AND ARRAY TESTER

(75) Inventors: Chih Hung Tsai, Changhua County (TW); Po Yang Chen, Tainan City (TW); Chien Chih Hsiao, Jhonghe City (TW)

Correspondence Address: LOWE HAUPTMAN HAM & BERNER, LLP, 1700 DIAGONAL ROAD, SUITE 300, ALEXANDRIA, VA, 22314, US

(73) Assignee: HANNSTAR DISPLAY CORP., Taipei County (TW)

(21) Appl. No.: 12/775,909

(22) Filed: May 7, 2010

(30) Foreign Application Priority Data
May 11, 2009 (TW) 098115635

(51) Int. Cl. G01R 31/00

(52) U.S. Cl. 324/770

(57) ABSTRACT

A testing method for an optical tough panel includes the steps of: coupling a negative voltage to a common line to turn off an optical sensing element; coupling a positive voltage to a readout line; turning on a switching device to have the positive voltage charge the optical sensing element through the readout line and the switching element; turning off the switching element for a predetermined period of time; coupling the negative voltage to the readout line; turning on the switching element again to read a voltage variation of the optical sensing element through the readout line and the switching element; and analyzing the voltage variation. The present invention further provides an array tester.

### CROSS REFERENCE TO RELATED APPLICATION

This application claims the priority benefit of Taiwan Patent Application Serial Number 098115635, filed on May 11, 2009, the full disclosure of which is incorporated herein by reference.

### BACKGROUND

1. Field of the Invention

This invention generally relates to a testing method for an optical touch panel and an array tester and, more particularly, to a testing method for optical sensing elements of an optical touch panel and an array tester using the same.

2. Description of the Related Art

Before a liquid crystal display is fabricated, an electrical testing on all pixel units of a thin film transistor array included in the liquid crystal display will generally be performed so as to find out defective thin film transistor array in advance to reduce the manufacturing cost, to find out problems existed in the processes for manufacturing the thin film transistor array and to fix the defects tested to increase the manufacturing yield.

Conventional array testers have already been able to test defects in a thin film transistor array and to classify the defects tested. For example, U.S. Pat. No. 5,546,013, entitled “Array tester for determining contact quality and line integrity in a TFT/LCD”, discloses an array tester including first devices for activating cells of the array by applying gate pulses to the gate lines and pulses to the data lines; second devices for acquiring waveform from data lines of the array; third devices for sampling the waveforms at selected points in time; and a computer configured to classify the waveforms to indicate whether defects are present.

In recent years, the optical touch panel has become a popular product due to its superior operation convenience. Especially the optical touch panel integrated with amorphous silicon based third switch elements has lower manufacturing cost due to its high manufacturing compatibility.

However, conventional array testers do not have the function for testing optical sensing elements of an optical touch panel. Therefore, it is necessary to provide a testing method and a testing apparatus for testing the yield of optical sensing elements included in an optical touch panel so as to effectively determine whether the quality of all optical sensing elements of the optical touch panel meets the product specification.

### SUMMARY

The present invention provides a testing method for optical sensing elements of an optical touch panel and an array tester using the testing method that may test whether all optical sensing elements of the optical touch panel are at a normal operation, leakage or broken; and may determine the location of the optical sensing elements with electrical defects.

The present invention provides a testing method for an optical touch panel, which includes a plurality of pixel units arranged in a matrix. Each pixel unit includes a readout line, a common line, an optical sensing element and a switching element. The optical sensing element is coupled to the common line and the switching element. The readout line is coupled to the switching element. The testing method includes the steps of: coupling a negative voltage to the common line to turn off the optical sensing element; coupling a positive voltage to the readout line; turning on the switching element to allow the positive voltage to charge the optical sensing element; turning off the switching element for a predetermined period of time; coupling the negative voltage to the readout line; turning on the switching element again to read a voltage variation of the optical sensing element through the readout line; and analyzing the voltage variation.

The present invention further provides a testing method for an optical touch panel, which includes a plurality of pixel units arranged in a matrix. Each pixel unit includes a readout line, a common line, an optical sensing element and a switching element. The optical sensing element is coupled to the common line and the switching element. The readout line is coupled to the switching element. The testing method includes the steps of: coupling a positive voltage to the common line to turn on the optical sensing element; turning on the switching element to allow the readout line, the switching element, the optical sensing element and the common line to form a current path; and analyzing a current variation or a voltage variation of the readout line.

The present invention further provides an array tester configured to test optical sensing elements of an optical touch panel, which includes a plurality of pixel units arranged in a matrix. Each pixel unit includes a readout line, a common line, a switching element and the optical sensing element. The optical sensing element is coupled to the common line and the switching element. The readout line is coupled to the switching element. The array tester includes a test head, control unit and a processing unit. The test head includes a plurality of probes configured to respectively electrically contact a contact pad of the readout line. The control unit is coupled to the test head, and is configured to generate a first voltage to the readout line and to control the on/off state of the switching element to allow the first voltage to charge or discharge the optical sensing element. The processing unit is coupled to the test head and is configured to analyze a current variation or a voltage variation of the readout line to determine whether the optical sensing element is defective or not.

In the testing method for optical sensing elements of an optical touch panel and the array tester of the present invention, it is able to determine whether an optical sensing element in a pixel unit is electrically defective or not by analyzing a current variation or a voltage variation read by the readout line of the pixel unit, and the type of electrical defects may also be identified.

### BRIEF DESCRIPTION OF THE DRAWINGS

Other objects, advantages, and novel features of the present invention will become more apparent from the following detailed description when taken in conjunction with the accompanying drawings.

FIG. 1 shows a schematic circuit diagram of a pixel unit of an optical touch panel.

FIG. 2 shows a cross sectional diagram of an optical sensing element of the pixel unit shown in FIG. 1.

FIG. 3a shows a schematic diagram of the testing system of an optical touch panel in accordance with an embodiment of the present invention, wherein contact pads of the readout lines are not fabricated at the data line side neither at the gate line side.

FIG. 3b shows another schematic diagram of the testing system of an optical touch panel in accordance with an embodiment of the present invention, wherein contact pads of the readout lines are fabricated at the gate line side.

FIG. 3c shows another schematic diagram of the testing system of an optical touch panel in accordance with an embodiment of the present invention, wherein contact pads of the readout lines are fabricated at the data line side.

FIG. 4a shows a timing diagram of the testing method for optical sensing elements of an optical touch panel in accordance with an embodiment of the present invention.

FIG. 4b shows a flow chart of the testing method for optical sensing elements of an optical touch panel in accordance with an embodiment of the present invention.

FIG. 5a shows a timing diagram of the testing method for optical sensing elements of an optical touch panel in accordance with another embodiment of the present invention.

FIG. 5b shows a flow chart of the testing method for optical sensing elements of an optical touch panel in accordance with another embodiment of the present invention.

### DETAILED DESCRIPTION OF THE EMBODIMENT

It should be noted that, wherever possible, the same reference numbers will be used throughout the drawings to refer to the same or like parts.

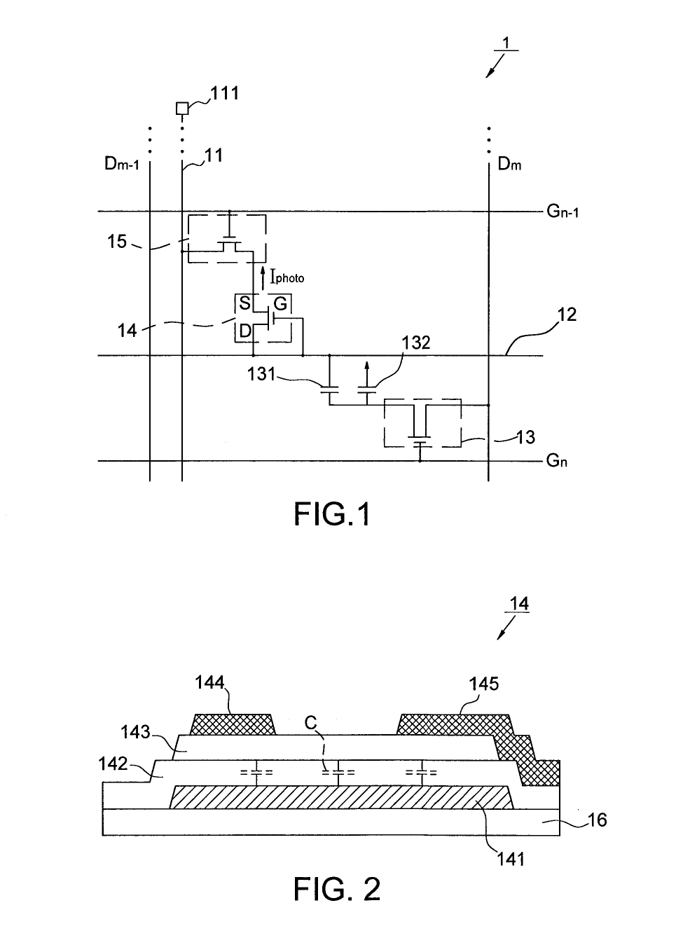

Please refer to FIG. 1, it shows a circuit schematic diagram of a pixel unit 1 of an optical touch panel. The optical touch panel includes a pixel array that includes a plurality of pixel units arranged in a matrix, and the pixel unit 1 shown in FIG. 1 is one of those pixel units. The pixel unit 1 includes a first gate line Gₙ₋₁, a second gate line Gₙ, a first data line Dₘ₋₁ and a second date line Dₘ together defining the pixel unit 1. The pixel unit 1 normally further includes a readout line 11, a common line 12, a pixel transistor 13, an optical sensing element 14 and a switching element 15, wherein the pixel transistor 13, the optical sensing element 14 and the switching element 15 may be thin film transistors. When the second gate line Gₙ turns on the pixel transistor 13, the second date line Dₘ charges a liquid crystal capacitor 131 and a storage capacitor 132 through the pixel transistor 13. The optical sensing element 14 includes a gate electrode G, a source electrode D and a drain electrode D; the gate electrode G and the drain electrode D are coupled to the common line 12, and the source electrode S is coupled to the switching element 15. The optical sensing element 14 is configured to absorb light energy to generate a photo current Iₚₕₒₜₒ. When the first gate line Gₙ₋₁ turns on the switching element 15, the photo current Iₚₕₒₜₒ may flow to the readout line 11 through the switching element 15. It is appreciated that the pixel unit 1 shown in FIG. 1 only shows a part of components for illustrating the present invention and omits other components. Furthermore, the disposition of the components included in FIG. 1 is only an embodiment of the pixel unit 1 and the testing method of the present invention is not limited to this kind of pixel structure.

Please refer to FIGS. 1 and 2, FIG. 2 shows an exemplary cross sectional view of the optical sensing element 14. The optical sensing element 14 generally includes a substrate 16, a first mental layer 141 (e.g. the gate electrode), an insulating layer 142, an amorphous silicon layer 143 and second mental layers 144, 145 (e.g. the source electrode and the drain electrode). The first mental layer 141 is disposed on the substrate 16 and coupled to the common line 12. The insulating layer 142 insulates the first mental layer 141. The amorphous layer 143 is formed on the insulating layer 142 and above the first mental layer 141 and served as a channel. The second mental layers 144 and 145 are respectively formed upon two sides of the amorphous silicon layer 143. It should be understood that FIG. 2 only shows a part of components included in the optical sensing element 14 for illustrating the present invention and omits other components. Furthermore, the disposition of the components included in FIG. 2 is not used to limit the testing method of the present invention to this structure.

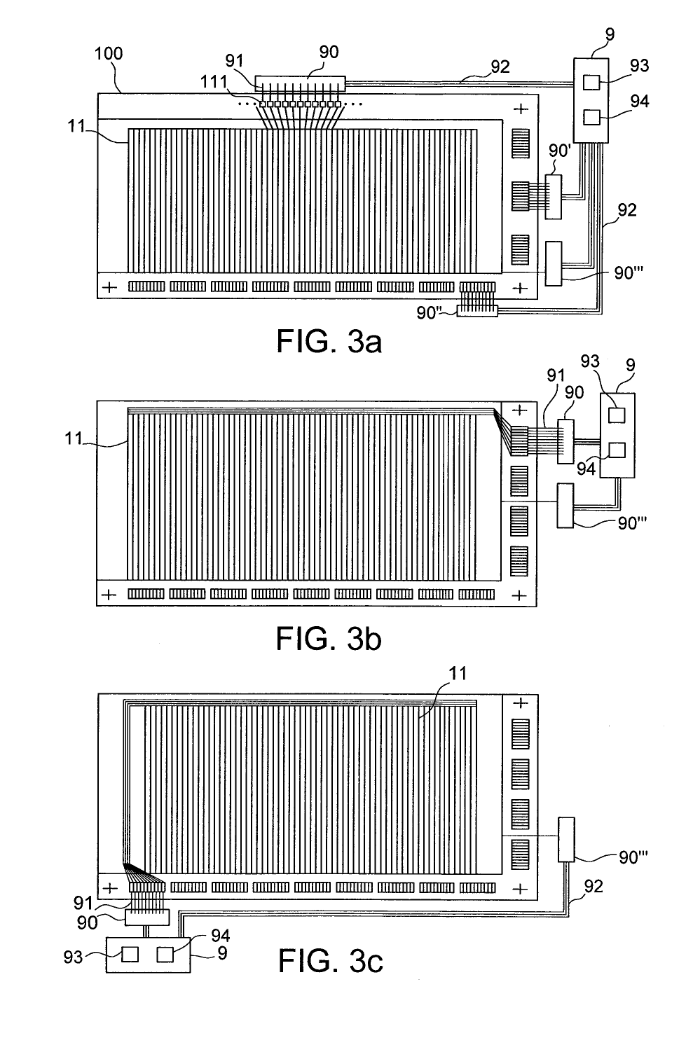

Please refer to FIGS. 3a to 3c, they respectively show a schematic diagram of a testing system of the optical touch panel in accordance with an embodiment of the present invention. The testing system includes an array tester 9 and a touch panel 100. The array tester 9 includes a test head 90, at least one signal transmission line 92, a control unit 93 and a processing unit 94. In addition, the array tester 9 may further includes a gate test head 90′ and a source test head 90″ configured to test the electrical property of date lines, and a common line test head 90′″ electrically connected to the common lines. The test head 90 includes a plurality of test probes 91 electrically connected to the contact pad 111 of a readout line 11. The signal transmission line 92 transmits signals between the test heads 90, 90′, 90″, 90′″ and the control unit 93 and the processing unit 94. It is appreciated that, FIGS. 3a to 3c only show a part of components for illustrating the present invention and omit other components. In addition, in FIGS. 3a to 3c, the gate test head 90′ and the source test head 90″ are omitted for simplifying the drawings.

The touch panel 100 includes a plurality of pixel units 1 (as shown in FIG. 1) arranged in a matrix. During testing, readout lines 11 of every column of pixel units 1 in a pixel area are wired outside the pixel area to be coupled to a contact pad 111 respectively. The array tester 9 electrically connects to the test head 90 through the signal transmission line 92. The test head 90 includes a plurality of test probes 91 configured to electrically connect to a contact pad 111 respectively. A control unit 93 and a processing unit 94 are included inside the array tester 9. The control unit 93 is configured to transmit control signals and voltage signals to the touch panel 100. The processing unit 94 is configured to analyze a current variation or a voltage variation of the readout line to determine the electrical property of the optical sensing element 14 and to classify the defects. In addition, according to different manufacturing processes and structures, the contact pad 111 of the readout line 11 may be formed in a side of the touch panel 100 without gate lines and data lines, as shown in FIG. 3a; may be formed in the gate line side of the touch panel 100, as shown in FIG. 3b; or may be formed in the data line side of the touch panel 100, as shown in FIG. 3c. The testing method for optical sensing elements of an optical touch panel of the present invention may be adapted in different touch panels as long as the position of the test head 90 is arranged corresponding to the position of contact pads 111 of the readout lines 11.

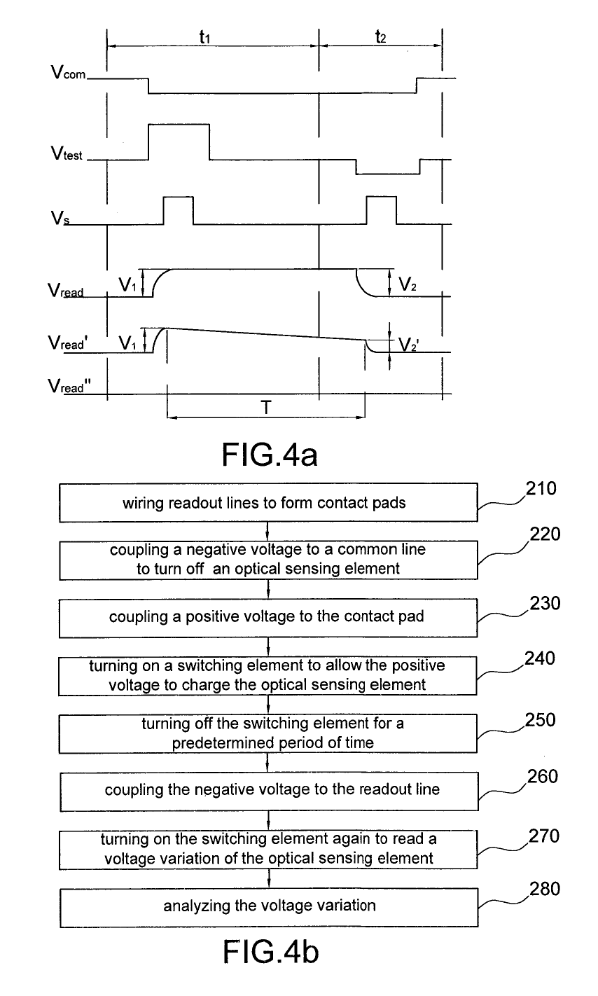

Please refer to FIGS. 1, 2 and 4a, an embodiment of the testing method for optical sensing elements of an optical touch panel will be illustrated hereinafter. First, during testing, every readout line 11 in the pixel area has to be wired outside the pixel area to form a contact pad 111, wherein all contact pads 111 are configured to electrically connect to an array tester 9. For example, the array tester 9 may electrically connect to the contact pads 111 through test probes 91 of the test head 90. Within a write period t₁, a negative voltage (V_{com}) is coupled to the common line 12 through the common line test head 90′″, wherein the negative voltage may be provided by the control unit 93 of the array tester 9 or provided by other means, and the value of the negative voltage is set to be able to turn off the optical sensing element 14. Accordingly the first mental layer 141 of the optical sensing element 14 changes to negative potential to turn off the optical sensing element 14. Next, the control unit 93 of the array tester 9 transmits a positive voltage (Vₜₑₛₜ) to the contact pad 11 and the readout line 11 for a proper period of time, wherein the negative voltage and the positive voltage may be transmitted to the common line 12 and the contact pad 11 at or not at the same time. When the common line 12 changes to negative potential and the readout line 11 changes to positive potential, the switching element 15 is turned on through the first gate line Gₙ₋₁, e.g. a control signal (Vₛ) may be sent to the first gate line Gₙ₋₁ from the control unit 93 of the array tester 9 to turn on the first gate line Gₙ₋₁. In this manner, the stray capacitor C existed between the first mental layer 141 and the amorphous silicon layer 143 of the optical sensing element 14 is charged to a predetermined potential (e.g. V₁ shown in FIG. 4a). Next, during a period that the common line 12 is at a negative potential and the readout line 11 is at a positive potential, the switching element 15 is turned off by the first gate line Gₙ₋₁ for a predetermined period of time.

Within a read period t₂, the common line 12 is still maintained at a negative potential. At this moment, a negative voltage (Vₜₑₛₜ) is coupled to the contact pad 111 and the readout line 11 by the array tester 9 for a proper period of time, wherein the negative voltage may be provided by the control unit 93 of the array tester 9 or provided by other means. Preferably, a value of the negative voltage (Vₜₑₛₜ) is equal to the negative voltage coupled to the common line 12 so as to accurately acquire a voltage variation of the optical sensing element 14. Next, during the period that the common line 12 and the readout line 14 are at a negative potential, the control unit 93 turns on the switching element 14 through the first gate line Gₙ₋₁ again. Accordingly, the processing unit 94 of the array tester 9 may read residual charges left in the stray capacitor C through the readout line 11 and contact pad 111 and analyzes the voltage variation thereof to determine whether the optical sensing element 14 is at a normal operation, leakage or broken. For example in FIG. 4a, when the potential read by the processing unit 94 is shown as V_{read}, i.e. a second potential V₂ is substantially equal to a first potential V₁ that is a predetermine potential that the stray capacitor C is charged during the write period t₁, the optical sensing element 14 is at a normal operation. When the potential read by the processing unit 94 is shown as V_{read}′, i.e. a second potential V₂′ is smaller than the first potential V₁, the optical sensing element 14 is leakage. When the potential read by the processing unit 94 is shown as V_{read}″, i.e. a zero potential, the optical sensing element 15 is not electrically connected to the optical sensing element 14.

In conclusion, when the switching element 15 is turned on within the write period t₁, the stray capacitor C is charged to the first potential V₁. When the switching element 15 is turned on again within the read period t₂, the stray capacitor C discharges (i.e. leaks) to the second potential V₂; wherein when the second potential V₂ is substantially equal to the first potential V₁, the processing unit 94 determines that the optical sensing element 14 is at a normal operation; when the second potential V₂ is smaller than the first potential V₁, the optical sensing element is determined to be leakage; and when the second potential V₂ is substantially equal to zero, the optical sensing element 14 is determined to be broken.

In addition, the length of the write period t₁ and the read period t₂ shown in FIG. 4a may be determined according to the actual application, and the time to transmit the positive and negative pulses and the length of the positive and negative pulses may also be determined according to the actual application. In addition, a holding time T, an interval that the control unit 93 of the array tester 9 successively turns on the switching element 15, may be used to determine detailed operation information of the optical sensing element 14. For example, a relationship diagram may be made according to the holding time T and residual charges read by the processing unit 94 such that a leakage resistance of the optical sensing element 14 may be calculated. In an embodiment, the holding time T may be set as one frame time, such that actual operation property of the optical sensing element 14 may be obtained according to the test results.

In conclusion, an embodiment of the testing method for optical sensing elements of an optical touch panel is shown in FIG. 4d and includes the steps of: wiring readout lines to form contact pads (step 210); coupling a negative voltage to a common line to turn off an optical sensing element (step 220); coupling a positive voltage to the contact pad (step 230); turning on the switching element to allow the positive voltage to charge the optical sensing element (step 240); turning off the switching element for a predetermined period of time (step 250); coupling the negative voltage to the readout line (step 260); turning on the switching element again to read a voltage variation of the optical sensing element through the readout line (step 270); and analyzing the voltage variation (step 280). Since details of the testing method were illustrated in the paragraphs above, they will not be repeated herein.

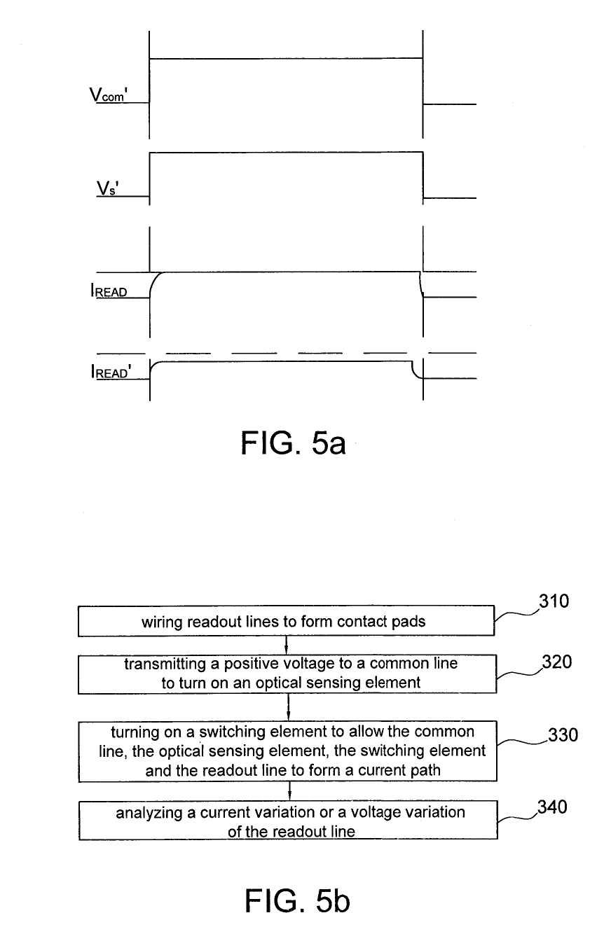

Please refer to FIGS. 1, 2 and 5a, another embodiment of the testing method for optical sensing elements of an optical touch panel of the present invention will be illustrated hereinafter. First, during testing, every readout line 11 in a pixel area also has to be wired outside the pixel area to form a contact pad 111, wherein the contact pads 111 are configured to electrically connect to the test head 90 of the array tester 9. A positive voltage (V_{com}′) is coupled to the common line 12 through a common line test head 90′″, wherein the positive voltage may be provided by the control unit 93 of the array tester 9 or by other means. Accordingly the first mental layer 141 of the optical sensing element 14 changes to positive potential to turn on the optical sensing element 14. Next, after or when the common line 12 changes to a positive potential, the switching element 15 is turned on through the first gate line Gₙ₋₁, e.g. the control unit 93 of the array tester 9 may send a control signal (Vₛ′) to the first gate line Gₙ₋₁ to turn on the switching element 15. Accordingly, a current path may be formed on the common line 12, the optical sensing element 14, the switching element 15 and the readout line 22 and coupled to the contact pad 111 and the array tester 9. The processing unit 94 of the array tester 9 may read a current variation of the optical sensing element 14 through the contact pad 111 and the readout line 11 and analyzes the current variation to determine whether the optical sensing element 14 has electrical defects. For example, when the current variation read by the processing unit 94 is shown as I_{READ} in FIG. 5a, i.e. the current is equal to a predetermined current, the optical sensing element 14 is at a normal operation. When the current variation read by the processing unit 94 is shown as I_{READ}′, i.e. the current is smaller than the predetermined current, the optical sensing element 14 has defects; wherein the predetermined current may be calculated in advance according to circuit parameters. In another embodiment, the current variation read by the processing unit 94 may be firstly converted to a voltage variation and then acquired by the processing unit 94, i.e. the array tester 9 has the function for converting current to voltage or vice versa.

In conclusion, the processing unit 94 of the array tester 9 compares the acquired current variation or the acquired voltage variation with a predetermined current or voltage so as to determine whether the optical sensing element 14 operates normally. In an embodiment, the voltage variation or current variation read by the processing unit 94 may be converted to digital information by means of an ADC unit, and the operation of the optical sensing element 14 may be determined according to the digital information. In addition, the time for sending the positive voltage and a length of the positive pulse shown in FIG. 5a may be determined according to the actual application, and they are not limited to that shown in FIG. 5a.

In conclusion, another embodiment of the testing method for optical sensing elements of an optical touch panel is shown in FIG. 5b and includes the steps of: wiring readout lines to form contact pads (step 310); coupling a positive voltage to a common line to turn on an optical sensing element (step 320); turning on a switching element to allow the common line, the optical sensing element, the switching element and the readout line to form a current path (step 330); and analyzing a current variation or a voltage variation of the readout line (step 340). In addition, since details of the testing method were illustrated in the paragraphs above, they will not be repeated herein.

In addition, in another embodiment, the testing method for optical sensing elements of an optical touch panel of the present invention may sequentially perform the testing procedures shown in FIGS. 4b and 5b. For example, procedures shown in FIG. 4b may be performed in a first time period and then procedures shown in FIG. 5b may be performed in a second time period subsequent to the first time period; or procedures shown in FIG. 5b may be performed in a first time period and then procedures shown in FIG. 4b may be performed in a subsequent second time period, wherein a testing sequence may be previously set in the array tester 9. For example, in an embodiment, the testing method for optical sensing elements of an optical touch panel includes the steps of: within a first time period, coupling a negative voltage to the common line to turn off the optical sensing element; coupling a positive voltage to the readout line; turning on the switching element to allow the positive voltage to charge an optical sensing element; turning off the switching element for a predetermined period of time; coupling the negative voltage to the readout line; turning on the switching element again to read a first voltage variation of the optical sensing element through the readout line; turning off the switching element; within a second time period, coupling a positive voltage to the common line to turn on the optical sensing element; turning on the switching element to allow the readout line, the switching element, the optical sensing element and the common line to form a current path to output a second voltage variation or a current variation; and analyzing the first voltage variation and the second voltage variation or the current variation. Since details of the testing method were illustrated in the paragraphs above, they will not be repeated herein.

As mentioned above, as conventional array testers do not have the function for testing optical sensing elements and therefore they can not be adapted to the testing for current optical touch panels. The present invention provides a testing method for optical sensing elements of an optical touch panel (FIGS. 4b and 5b) and an array tester (FIGS. 3a to 3c) that analyze a current variation or a voltage variation read by an array tester through readout lines to determine whether all optical sensing elements of an optical touch panel are at a normal operation, leakage or broken, and further to determine the position of optical sensing elements with electrical defects.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A testing method for an optical touch panel, the optical touch panel comprising a plurality of pixel units arranged in a matrix, each pixel unit comprising a readout line, a common line, an optical sensing element and a switching element, the optical sensing element being coupled to the common line and the switching element, the readout line being coupled to the switching element, the testing method comprising the steps of:
coupling a negative voltage to the common line to turn off the optical sensing element;
coupling a positive voltage to the readout line;
turning on the switching element thereby allowing the positive voltage to charge the optical sensing element;
turning off the switching element for a predetermined period of time;
coupling the negative voltage to the readout line;
turning on the switching element again to read a voltage variation of the optical sensing element through the readout line; and
analyzing the voltage variation.

2. The testing method as claimed in claim 1, further comprising the step of: wiring the readout line to form a contact pad.

3. The testing method as claimed in claim 2, wherein the touch pad is at a side of the optical touch panel without data lines and gate lines, at the data line side or at the gate line side.

4. The testing method as claimed in claim 1, wherein the predetermined period of time is one frame period.

5. The testing method as claimed in claim 1, wherein in the step of analyzing the voltage variation further comprises the step of: determining the optical sensing element is at a normal operation, leakage or broken according to the voltage variation.

6. The testing method as claimed in claim 5, wherein the positive voltage charges the optical sensing element to a first voltage and the optical sensing element outputs a second voltage through the readout line, and the step of analyzing the voltage variation further comprises the steps of:
determining the optical sensing element to be at a normal operation when the second voltage is substantially equal to the first voltage;
determining the optical sensing element to be leakage when the second voltage is smaller than the first voltage; and
determining the optical sensing element to be broken when the second voltage is zero.

7. The testing method as claimed in claim 1, wherein the switching element is turned on when the common line is at a negative potential and the readout line is at a positive or a negative potential.

8. The testing method as claimed in claim 1, wherein the positive voltage and the negative voltage are provided by an array tester.

9. The testing method as claimed in claim 1, wherein the conduction of the switching element is controlled by an array tester.

10. A testing method for an optical touch panel, the optical touch panel comprising a plurality of pixel units arranged in a matrix, each pixel unit comprising a readout line, a common line, an optical sensing element and a switching element, the optical sensing element being coupled to the common line and the switching element, the readout line being coupled to the switching element, the testing method comprising the steps of:
coupling a positive voltage to the common line to turn on the optical sensing element;
turning on the switching element thereby allowing the readout line, the switching element, the optical sensing element and the common line to form a current path; and
analyzing a current variation or a voltage variation of the readout line.

11. The testing method as claimed in claim 10, further comprising the step of: wiring the readout line to form a contact pad.

12. The testing method as claimed in claim 11, wherein the current path is coupled to an array tester through the contact pad.

13. The testing method as claimed in claim 11, wherein the touch pad is at a side of the optical touch panel without data lines and gate lines, at the data line side or at with the gate line side.

14. The testing method as claimed in claim 10, wherein in the step of analyzing a current variation or a voltage variation of the readout line further comprises the step of: comparing the current variation or the voltage variation with a predetermined current or a predetermined voltage to determine the optical sensing element is normal or defective.

15. The testing method as claimed in claim 10, wherein the switching element is turned on when the common line is at a positive potential.

16. The testing method as claimed in claim 10, wherein the positive voltage is provided by an array tester.

17. An array tester, configured to test optical sensing elements of an optical touch panel, the optical touch panel comprising a plurality of pixel units arranged in a matrix, each pixel unit comprising a readout line, a common line, a switching element and the optical sensing element, the optical sensing element being coupled to the common line and the switching element, the readout line being coupled to the switching element, the array tester comprising:
a test head, comprising a plurality of probes configured to respectively electrically contact a contact pad of the readout line;
a control unit coupled to the test head, configured to generate a first voltage to the readout line and to control the on/off state of the switching element thereby allowing the first voltage to charge or discharge the optical sensing element; and
a processing unit coupled to the test head, configured to analyze a current variation or a voltage variation of the readout line to determine whether the optical sensing element is defective.

18. The array tester as claimed in claim 17, wherein the control unit further generates a second voltage to the common line to control the on/off state of the optical sensing element.

19. The array tester as claimed in claim 18, wherein the first voltage and the second voltage are positive or negative.

20. The array tester as claimed in claim 17, wherein the array tester has the function of converting a current to a voltage or converting a voltage to a current.
